(19) United States
(12) Patent Application Publication
(10) Pub. No.: US 2025/0107206 A1
(43) Pub. Date: Mar. 27, 2025

(54) CURVED-GATE TRANSISTOR STRUCTURE

(71) Applicant: Silergy Semiconductor Technology (Hangzhou) LTD., Hangzhou (CN)

(72) Inventors: Zaiwei SUN, Hangzhou (CN); Huafeng YUAN, Hangzhou (CN); Gang YAO, Hangzhou (CN); Yidan CHEN, Hangzhou (CN); Xiaoyan LOU, Hangzhou (CN)

(73) Assignee: Silergy Semiconductor Technology (Hangzhou) LTD., Hangzhou (CN)

(21) Appl. No.: 18/892,513

(22) Filed: Sep. 22, 2024

(30) Foreign Application Priority Data
Sep. 22, 2023 (CN) 2023112398023

(51) Int. Cl. H01L 29/423; H01L 27/02; H01L 27/085; H01L 29/08; H01L 29/10

(52) U.S. Cl. CPC H10D 64/411; H10D 62/149; H10D 62/393; H10D 84/82; H10D 89/60

(57) ABSTRACT

A curved-gate transistor structure, wherein gate regions of the curved-gate transistor structure are curved, wherein the curved-gate transistor structure comprises semiconductor structural units, each semiconductor structural unit further comprises body contact regions, the body contact regions and source region are on the same side of the gate region, each semiconductor structural unit further comprises a curved gate region; the body contact regions are added near the source region, and contact regions of each of the semiconductor structural units structure can easily form a network to enhance latch-up resistance; each of the first metal blocks can be connected to a same or different potential, and the two branches of the gate regions of the same semiconductor structural unit can also be connected to a same or different potential.

### FIELD OF TECHNOLOGY

The present disclosure belongs to the field of semiconductor devices, in particular it relates to a curved-gate transistor structure.

### BACKGROUND

The channel length and channel width of a MOS transistor are essential parameters. A greater channel aspect ratio leads to a higher saturation current and improves performance of the MOS transistor. Consequently, some circuit designs require transistors with larger channel widths. Shown in FIG. 1a is a structure of a conventional transistor; in order to increase the channel width W of a MOS transistor to obtained a larger channel width W′, one would typically enlarge the overlap area between the active region and the polysilicon as shown in FIG. 1b. However, this approach increases the overall area of the MOS transistor, and thus is disadvantageous for the semiconductor device design and hinders improvements in the power density of the transistor. Therefore, developing a transistor structure that enhances power density while maintaining device performance has become a pressing challenge for professionals in this field.

### SUMMARY

The present disclosure proposes a curved-gate transistor structure to address the technical issue of improving device power density while maintaining device performance.

In first aspect, the present disclosure provides a curved-gate transistor structure, including M*N semiconductor structural units arranged in an M*N array, wherein M and N are both positive integers; wherein each of the semiconductor structural units includes a gate region, a source region, and a drain region, wherein the source region is located on a first side of the gate region, and the drain region is located on a second side of the gate region, wherein the first side may be an outer side of the gate region, and the second side may be an inner side of the gate region; wherein the gate region of each semiconductor structural unit is curved, wherein each of the semiconductor structural units includes a convex unit surrounded by the gate region of the semiconductor structural unit, and the convex unit has a convex shape; wherein when N>1, gate regions of each two adjacent semiconductor structural units in a same row are connected with each other; and wherein each semiconductor structural unit further includes body contact regions, the body contact regions are connected with a well region or a substrate where the source region and the drain region of the corresponding semiconductor structural unit are located, wherein the body contact regions and the source region are both on the first side of the gate region.

Preferably, the gate region of each semiconductor structural unit includes two curved branches, and the two branches are separated from each other and located above an active region where the semiconductor structure unit is located; wherein each of the branches of the gate region is symmetric with respect to a first straight line, and the two branches are symmetric with respect to a second straight line; wherein the first straight line and the second straight line both pass through a center of the semiconductor structural unit and are perpendicular to each other; wherein when N>1, branches of the gate regions of each two adjacent semiconductor structural units in the same row are correspondingly connected with each other; for example, an upper branch of the gate region of a first semiconductor structural unit is connected to an upper branch of the gate region of a second semiconductor structural unit adjacent to the first semiconductor structural unit; and a lower branch of the gate region of the first semiconductor structural unit is connected to a lower branch of the gate region of the second semiconductor structural unit.

Preferably, in each semiconductor structural unit, the source region or the drain region is located directly below the convex unit.

Preferably, each of the branches of the gate region of each semiconductor structural unit includes multiple straight segments, and angles between adjacent straight segments are obtuse angles.

Preferably, junctions between the adjacent straight segments of each of the branches are arced.

Preferably, each semiconductor structural unit further includes one or more drain contact regions and one or more source contact regions; wherein the drain contact regions are located on the drain region, and wherein the source contact regions are located on the source region.

Preferably, each branch of the gate region of each semiconductor structural unit includes 4k+1 straight segments, wherein a first straight segment, a 2k+1th straight segment and a 4k+1th straight segment of each branch are parallel to each other, and wherein k is a positive integer.

Preferably, in each semiconductor structural unit, contact regions are provided between first straight segments of the two branches of the gate region, and between 4k+1th straight segments of the two branches of the gate region.

Preferably, when M>1, contact regions are provided between 2k+1th straight segments of two adjacent branches of two adjacent semiconductor structural units located in the same column.

Preferably, each semiconductor structural unit further includes first metal blocks and second metal blocks, wherein the second metal blocks are connected to the drain contact regions, and wherein the first metal blocks are connected to the source contact regions and the body contact regions; wherein in each semiconductor structural unit, the first metal blocks are plural or the second metal blocks are plural; wherein the first metal blocks and the second metal blocks are rectangular; and wherein the first metal blocks and the second metal blocks are parallel and alternating in a width direction of the semiconductor structural unit.

Preferably, the first metal blocks and the second metal blocks are parallel and alternating along a first direction, wherein the first metal blocks and the second metal blocks have equal lengths along a second direction, wherein the first direction is parallel to the first straight segment of each branch of the gate region in each semiconductor structural unit, and wherein the second direction is perpendicular to the first direction.

Preferably, the first metal blocks and the second metal blocks are parallel and alternating along a second direction, wherein the first metal blocks and the second metal blocks have equal lengths along a first direction, wherein the first direction is parallel to the first straight segments of each branch of the gate region in each semiconductor structural unit, and wherein the second direction is perpendicular to the first direction.

Preferably, when M>1, all branches of the gate regions of the curved-gate transistor structure are connected to a same potential through a fifth metal block.

Preferably, a total width of all the first metal blocks is equal to that of all the second metal blocks.

Preferably, when M>1, gate regions of the semiconductor structural units located in different rows are connected to different potentials.

Preferably, the two branches of each semiconductor structural unit are connected to two different potentials.

Preferably, each of the first metal blocks is connected to a different potential.

Preferably, some of the first metal blocks are connected to a same potential.

Preferably, contact regions within each convex unit includes the body contact regions and the source contact regions, and exhibit axial and central symmetry in their arrangement, and each row of the contact regions are either all body contact regions or all source contact regions.

Preferably, the contact regions within each convex unit are arranged in a rectangular array.

Preferably, the contact regions within each convex unit are arranged in one column.

Preferably, the source contact regions and the body contact regions are alternately arranged in one column.

Preferably, a quantity of contact regions in a first row within each convex unit is the same as that of a last row, and less than a quantity of contact regions in each intermediate row.

Preferably, contact regions in a first row and a last row within each convex unit are of the same type, and said type is different from that of intermediate rows of the convex unit.

Compared to related technologies, the technical solution of the present disclosure has the following beneficial effects:
a. the presently disclosed curved gate regions of the curved-gate transistor structure can increase the channel width and enhance power density of the transistor structure;
b. the diagonal design of the source contact regions and the drain contact regions impart certain electrostatic discharge (ESD) protection characteristics to each of the semiconductor structural units, enhancing the current-limiting capability of the source and drain;
c. in each gate region, the angles between the adjacent straight segments are obtuse, which reduces the likelihood of local avalanche breakdown compared to designs with 90° or acute angles, thereby enhancing stability of the transistor structure;
d. the body contact regions are added near the source region, and the contact regions can easily form a network to enhance latch-up resistance, by adjusting the density of the body contact regions and the relative arrangement between the body contact regions and the drain contact regions according to design requirements, the transistor structure can better handle frequent transient overload situations without excessively increasing the area;
e. when all semiconductor structural units form a power transistor, the total width of all the first metal blocks is equal to that of all the second metal blocks; this design not only increases current capability but also improves the uniformity of the current;
f. in each of the semiconductor structural units, contact holes may be set between the first straight segments of the two branches and between the 4k+1th straight segments of the two branches, and contact holes may also be set between the 2k+1th straight segments of adjacent branches in neighboring semiconductor structural units aligned in the same column; this arrangement increases the number and placement of contact holes, thereby enhancing the performance and power density of the device;
g. according to design requirements, the two branches of the same semiconductor structural unit can be connected to same or different potentials, wherein each of gate branches and each of the first metal blocks can also be connected to a same or different potential; this flexibility allows for the configuration of one or more common-source transistors from all semiconductor structural units, enhancing design adaptability.

### BRIEF DESCRIPTION OF THE DRAWINGS

By referring to the following figures for the description of embodiments of the present disclosure, the above-mentioned and other objectives, features, and advantages of the present disclosure will become more apparent:

FIGS. 1a-1b are schematic diagrams of transistors in existing technologies.

FIGS. 2a-2b are schematic diagrams of two embodiments of a semiconductor structural unit according to the present disclosure.

FIGS. 3a-3b are schematic diagrams of two embodiments of a gate region within a semiconductor structural unit according to the present disclosure.

FIGS. 4a-4b are schematic diagrams of two embodiments of metal blocks within a semiconductor structural unit according to the present disclosure.

FIGS. 5a-5b are schematic diagrams of two embodiments of a curved-gate transistor structure according to the present disclosure.

FIG. 6 is a schematic diagram of a third embodiment of a curved-gate transistor structure according to the present disclosure.

FIGS. 7a-7b are schematic diagrams of a fourth and a fifth embodiment of a curved-gate transistor structure according to the present disclosure.

FIGS. 8a-8c are schematic diagrams of three embodiments of contact regions in a convex unit of the present disclosure.

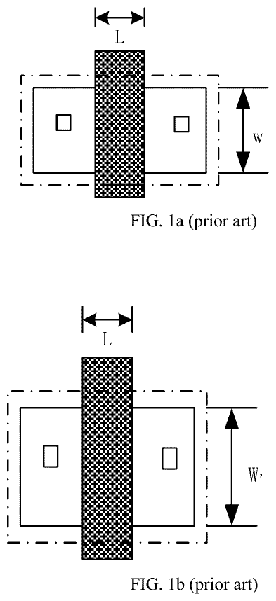

### DETAILED DESCRIPTION

The following description is based on embodiments of the present disclosure, but the disclosure is not limited to these embodiments. In the detailed description of the present disclosure that follows, some specific details are described in depth. Those skilled in the art can fully understand the disclosure even without the description of these specific details. Well-known methods, processes, procedures, components, and circuits are not described in detail so as not to confuse the essence of the disclosure.

Furthermore, those skilled in the art should understand that the accompanying drawings provided are for illustrative purposes only and are not necessarily to scale.

The present disclosure provides a curved-gate transistor structure, including M*N semiconductor structural units arranged in an M*N array, wherein M and N are both positive integers; each of the semiconductor structural units includes an active region, a gate region, a source region and a drain region, wherein the gate region is located over the active region and separates the source and drain regions, and the gate region of each semiconductor structural unit is curved; and each semiconductor structural unit further includes body contact regions, the body contact regions are connected with a well region or a substrate where the source region and the drain region of the corresponding semiconductor structural unit are located, and the body contact regions and the source region are both on the first side of the gate region, wherein the first side can be an outer side or an inner side of the gate region, and the second side can be the inner side or the outer side of the gate region, wherein when N>1, branches of the gate regions of each two adjacent semiconductor structural units in the same row are correspondingly connected with each other, for example, an upper branch of the gate region of a first semiconductor structural unit is connected to an upper branch of the gate region of a second semiconductor structural unit adjacent to the first semiconductor structural unit; and a lower branch of the gate region of the first semiconductor structural unit is connected to a lower branch of the gate region of the second semiconductor structural unit.

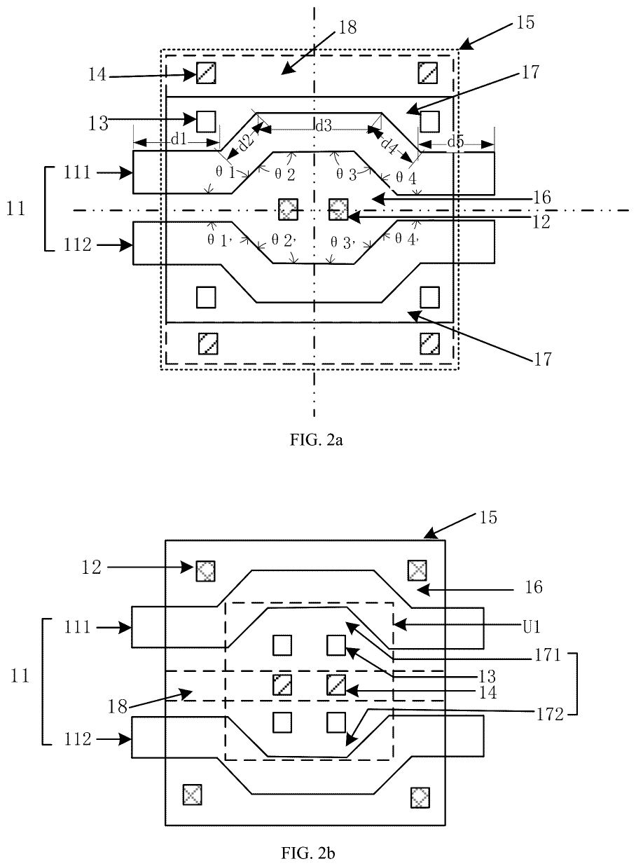

Further, each of the semiconductor structural units will be explained; FIGS. 2a-2b are schematic diagrams of two embodiments of a semiconductor structural unit according to the present disclosure. The gate region 11 of each semiconductor structural unit includes two branches: a first branch of the gate region 111 and a second branch of the gate region 112, and the two branches of each semiconductor structural unit are separated from each other above an active region 15. Each of the branches of the gate region of each semiconductor structural unit includes multiple straight segments, and angles between adjacent straight segments are obtuse angles. Additionally, the straight segments intersecting the boundary of the active region 15 are parallel to one of the edges of the active region 15. A width of each straight segment is equal. The active region 15 is located beneath the gate region 11, and the active region 15 is rectangle. As shown in the FIGS. 2a-2b, as an example, each branch includes five straight segments. In the first branch, segments d1, d2, d3, d4, and d5 are of equal width, with an obtuse angle of 135° between each pair of adjacent straight segments. In the second branch, the angle between each pair of adjacent straight segments is also 135°. Both the first segment d1 and the fifth segment d5 are parallel to one of the horizontal edges of the active region 15, which means they are perpendicular to one of the vertical edges of the active region 15. As shown in the FIGS. 2a-2b, each of the semiconductor structural units includes a convex unit surrounded by the gate region of the semiconductor structural unit, each convex unit is centrally symmetric and symmetrical about both horizontal and vertical axes thereof, and the convex unit has a convex shape. As shown in a dashed rectangle in FIG. 2b, the convex unit U1 is surrounded by two branches of the gate region from the same semiconductor structural unit, excluding the area between the first straight segments of the two branches and the area between the 4k+1 straight segments of the two branches. As shown in FIG. 2a, each of the branches of the gate region is symmetric with respect to a first straight line, and the two branches are symmetric with each other with respect to a second straight line; wherein the first straight line is the vertical dashed line that passes through the center of the semiconductor structural unit, and the second straight line is the horizontal dashed line that is perpendicular to the first straight line.

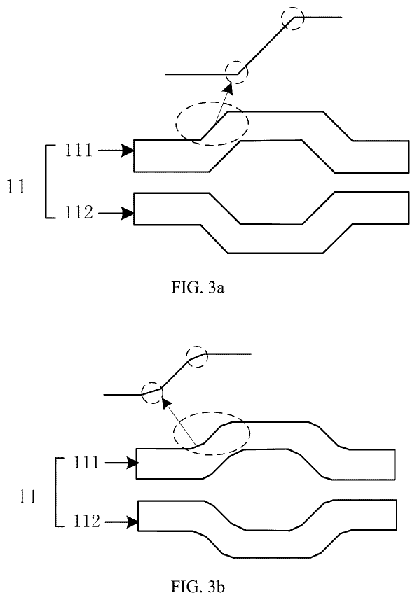

It should be noted that, as shown in FIGS. 2a-2b and FIG. 3a, in each gate region, the angle between the adjacent straight segments within each branch is obtuse, which is prone to charge accumulation and local avalanche breakdown compared to designs with 90° or acute angles, thereby enhancing stability of the transistor structure. In one embodiment as shown in FIG. 3b, the obtuse angle at the connection between the two adjacent straight segments can be further refined by introducing more straight segments to approximate an arc shape, thereby achieving a smoother transition at the obtuse angle, thereby making the entire line composed of d1, d2, d3, d4, and d5 approximate an arc or a curved shape. Compared to FIG. 3a and FIG. 2a, in FIG. 2b the angle between two adjacent straight segments is smoother and less likely to accumulate charges, thereby improving the performance of the device. As another example, the number of straight segments in each branch of the gate region of a semiconductor structural unit may also be any 4k+1, such as 9 or 13, with the first straight segment, the 2k+1th straight segment, and the last 4k+1th straight segment being parallel to each other, where k is a positive integer. The number and shape of straight segments in the gate region of each semiconductor structural unit are not restricted, as long as the gate region is horizontally and vertically axisymmetric. Additionally, the gate region of the semiconductor structural unit described in this embodiment also exhibits central symmetry.

As shown in FIG. 2a, in one embodiment, a drain region 16 is located between the two branches, specifically directly below the convex unit, and the source region 17 is located on an outer side of the gate region. As shown in FIG. 2b, in one embodiment, the source region 17 and a body doping region 18 are located between the two branches, specifically directly below the convex unit; the source region 17 is divided by the body doping region 18 into two parts, that is, a first source subregion 171 and a second source subregion 172; the drain region 16 is located on the outer side of the gate region 112.

It should be noted that the shape of the active region 15 of the semiconductor structural unit can also be of other shapes, regular or irregular. In other examples, the number of branches of each semiconductor structural unit can be greater than 2. In other designs, the branches of the gate region 11 can be interconnected to form a closed ring structure, with the drain region 16 located within this closed ring structure. However, by keeping the branches separate rather than interconnected, the width of the gate region can be increased, thereby significantly enhancing the power density of the device.

As shown in FIGS. 2a-2b, each semiconductor structural unit also includes one or more drain contact regions 12 and one or more source contact regions 13. The drain contact regions 12 are located over the drain region 16, and the source contact regions 13 are located over the source region 17. The semiconductor structural unit also includes body contact regions 14, and the body contact regions 14 are connected to a well region or substrate in which the source region 17 and drain region 16 are located, via the body doping region 18. The body doping region 18 is located in the same well region or substrate as the source region 17 and drain region 16, and it has the same doping type as the well region or substrate where the source region 17 and drain region 16 are located, but with a higher doping concentration than that of the well region or substrate. The body contact regions 14 and the source contact regions 13 are positioned on the same side (i.e., either inner side or outer side) of each branch of the gate region 11. In a first embodiment, as shown in FIG. 2a, each semiconductor structural unit includes two drain contact regions 12, the drain contact regions 12 are symmetrically arranged with respect to both the horizontal and vertical axes of the center of the semiconductor structural unit. This configuration ensures that the distance from the drain contact regions 12 to the gate region 11 is as equal as possible. Each semiconductor structural unit includes four source contact regions, each positioned diagonally with respect to the drain contact regions 12. Furthermore, the quantity of the body contact regions 14 is equal to that of the source contact regions 13, and each of the body contact regions 14 is located close to one of the source contact regions 13. The source contact regions 13 and body contact regions 14 are also symmetrically arranged with respect to both the horizontal and vertical axes of the center of the semiconductor structural unit. This arrangement ensures that the distance from the drain contact regions 12 to the source contact regions 13 is as equal as possible. In a second embodiment, as shown in FIG. 2b, each semiconductor structural unit includes four source contact regions 13, and these source contact regions 13 are symmetrically arranged with respect to the center of the semiconductor structural unit to ensure that the distance from each source contact region 13 to the gate region 11 is as equal as possible; the semiconductor structural unit also includes four drain contact regions 12, each positioned diagonally relative to the source contact regions 13. The four drain contact regions 12 are also symmetrically arranged with respect to the center of the semiconductor structural unit, ensuring that the distance from each drain contact region 12 to the source contact regions is as equal as possible.

It should be noted that in the above embodiments, the quantity and arrangement of the source contact regions 13, the drain contact regions 12, and the body contact regions 14 are shown merely for illustration purposes to demonstrate their relative positions. In other examples, the quantity and arrangement of these contact regions may vary, such as adjacent semiconductor structural units sharing one or more contact regions (which may also be source contact regions, drain contact regions, or body contact regions) either vertically or horizontally, or four semiconductor structural units arranged in a 2×2 matrix sharing one or more contact regions. In practical applications, as long as the process and dimensions allow, as many corresponding contact regions as possible can be added to enhance the performance of the device. In practical applications, the quantity or density of body contact regions 14 can be adjusted according to the specific requirements. Increasing the quantity or density of body contact regions 14 can enhance the latch-up immunity of the device. However, an excessive number of body contact regions 14 can occupy too much chip area. Therefore, the quantity or density of body contact regions 14 can be increased or decreased based on the actual needs of the device.

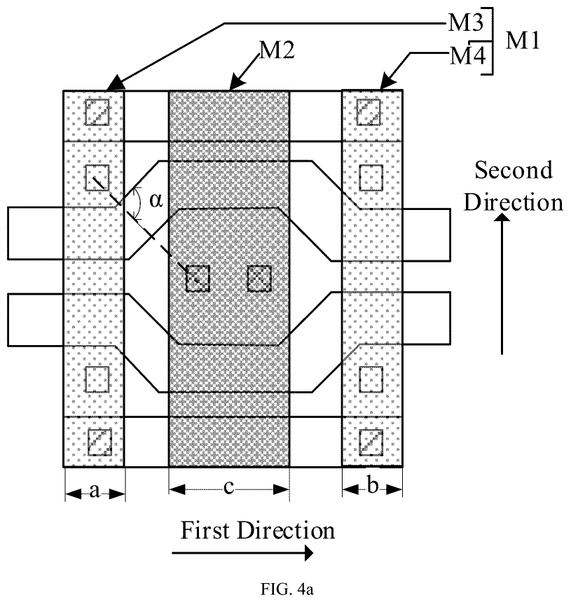

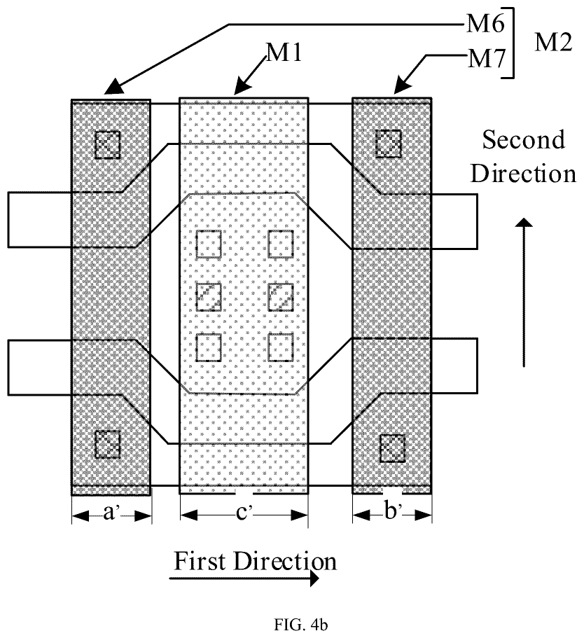

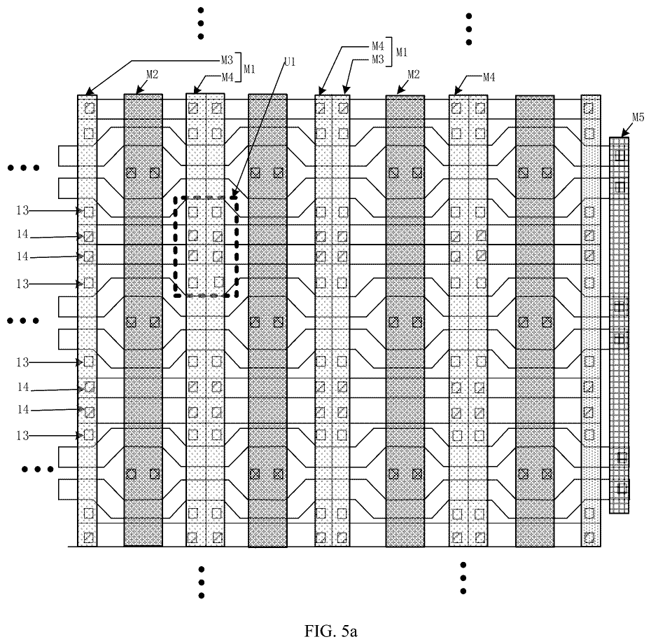

As shown in FIGS. 2a-2b, each of the drain contact regions 12 is arranged diagonally with one of the source contact regions 13 with respect to at least one branch of the gate region 11. This configuration can increase the distance between the source contact regions 13 and the drain contact regions 12 compared to the case of a straight gate region 11, the current limiting effect between the source contact regions 13 and the drain contact regions 12 is improved. Consequently, the device can have some ESD protection characteristics. In one embodiment, when θ1˜θ4 are all 135°, the line connecting each of the drain contact regions 12 with one of the source contact regions 13 is perpendicular to the straight segment of the gate region that intersects this line. Specifically, as shown in FIG. 4a, α is an angle between the third straight segment of the gate region and the line connecting one of the drain contact regions 12 and one of the source contact regions 13, where α=90°.

As shown in FIGS. 4a-4b, the semiconductor structural unit further includes first metal blocks M1 and second metal blocks M2 located above the active region and the gate region, wherein the second metal blocks M2 are connected to the drain contact regions 12, and the first metal blocks M1 are connected to the source contact regions 13 and the body contact regions 14.

Specifically, as shown in FIG. 4a, when the drain region is located between the two branches of the gate region, the drain region is located within the area of the convex unit, and the first metal blocks M1 include a third metal block M3 and a fourth metal block M4. The third metal block M3 and the fourth metal block M4 are positioned on opposite sides of the second metal block M2. The second metal block M2, the third metal block M3, and the fourth metal block M4 are all located above the gate region and the active region, each of these metal blocks is rectangle, and the second metal block M2, the third metal block M3, and the fourth metal block M4 are arranged in parallel along a first direction; the first direction is parallel to one edge of the active region 15, the first direction is also parallel to the first and last straight segments of each of the branches of the gate region. The second metal block M2, the third metal block M3, and the fourth metal block M4 have equal lengths along a second direction; the first direction and the second direction are as shown in FIGS. 4a-4b, with the second direction being perpendicular to the first direction.

Specifically, as shown in FIG. 4b, when the source region is located between the two branches of the gate region, the source region is located within the area of the convex unit, the second metal blocks M2 include a sixth metal block M6 and a seventh metal block M7. The sixth metal block M6 and the seventh metal block M7 are positioned on opposite sides of the first metal block M1; the first metal block M1, the sixth metal block M6, and the seventh metal block M7 are located above the gate region and the active region, each of these metal blocks is rectangle, and the sixth metal block M6, the first metal block M1, and the seventh metal block M7 are arranged are arranged in parallel along a first direction; the first direction is parallel to one of the right-angle sides of the active region 15, the first direction is also parallel to the first and last straight segments of each of the branches of the gate region. The first metal block M1, the sixth metal block M6, and the seventh metal block M7 have equal lengths along a second direction; the first direction and the second direction are as shown in FIG. 4b, with the second direction being perpendicular to the first direction.

In one embodiment, as shown in FIG. 4a, the sum of a length a of the third metal block M3 and a length b of the fourth metal block M4 along the first direction equals to the length c of the second metal block M2 along the first direction, i.e., a+b=c. As shown in FIG. 4a, the length a of the third metal block M3 along the first direction and the length b of the fourth metal block M4 along the first direction are set to be equal, and both are half of the length c of the second metal block M2 along the first direction, thereby improving current uniformity. As shown in FIG. 4b, the sum of a length a′ of the sixth metal block M6 and a length b′ of the seventh metal block M7 along the first direction equals to the length c′ of the first metal block M1 along the first direction, i.e., a′+b′=c′. As shown in FIG. 4b, the length a′ of the sixth metal block M6 along the first direction and the length b′ of the seventh metal block M7 along the first direction are set to be equal, and both are half of the length c′ of the first metal block M1 along the first direction, thereby improving current uniformity.

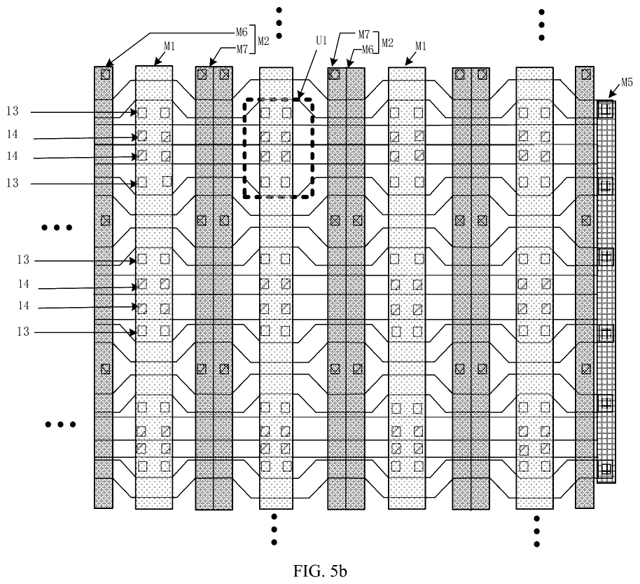

In one embodiment, as shown in FIG. 5a, the curved-gate transistor structure includes M*N semiconductor structural units as shown in FIG. 2a; when N>1, in each two adjacent semiconductor structural units (for example, including a first semiconductor structural unit on the left and a second semiconductor structural unit on the right) in a row, the fourth metal block M4 (on the right side of the second metal block M2 of the first semiconductor unit) of the first semiconductor structural unit is connected to the third metal block M3 (on the left side of the second metal block M2 of the second semiconductor unit) of the second semiconductor structural unit. In each two adjacent semiconductor structural units (for example, including the first semiconductor structural unit and a third semiconductor structural unit under the first semiconductor structural unit), the second metal blocks M2 of the first and third semiconductor units are connected to each other, the third metal blocks M3 of the first and third semiconductor units are connected to each other, and the fourth metal blocks M4 of the first and third semiconductor units are connected to each other. As shown in FIG. 5a, the fourth metal block M4 of the first semiconductor structural unit and the third metal block M3 of the second semiconductor structural unit are connected to each other, forming a first metal block M1. As shown in FIG. 5a, when the curved-gate transistor structure forms a power transistor, all branches of the gate regions in all rows of semiconductor units are connected to a fifth metal block M5, and the fifth metal block M5 links the branches together. When the total width of the first metal blocks equals the total width of the second metal blocks, and the width of the first metal blocks in the inner columns equals the width of the second metal blocks in the inner columns (note that metal blocks on the edges may have only partial widths), this helps achieve better current uniformity in the power transistor.

In one embodiment, as shown in FIG. 5b, the curved-gate transistor structure includes M*N semiconductor structural units as shown in FIG. 2b; when N>1, in each two adjacent semiconductor structural units (for example, including a first semiconductor structural unit on the left and a second semiconductor structural unit on the right) in a row, the seventh metal block M7 (on the right side of the first metal block M1 of the first semiconductor unit) of the first semiconductor structural unit is connected to the sixth metal blocks M6 (on the left side of the first metal block M1 of the second semiconductor unit) of the second semiconductor structural unit, forming a second metal block M2. In each two adjacent semiconductor structural units (for example, including the first semiconductor structural unit and a third semiconductor structural unit under the first semiconductor structural unit), the first metal blocks M1 of the first and third semiconductor units in the same column are connected to each other, the sixth metal blocks M6 of the first and third semiconductor units in the same column are connected to each other, and the seventh metal blocks M7 of the first and third semiconductor units in the same column are also connected to each other. As shown in FIG. 5b, when the curved-gate transistor structure forms a power transistor, all branches of the gate regions in all rows of semiconductor units are connected to a fifth metal block M5, and the fifth metal block M5 links the branches together. When the total width of the first metal blocks equals the total width of the second metal blocks and as shown in FIG. 5b, when the width of the first metal blocks M1 in the inner columns equals the width of the second metal blocks M2 in the inner columns (note that metal blocks on the edges may have only partial widths), which helps achieve better current uniformity in the power transistor.

As shown in FIGS. 5a-5b, two types of curved-gate transistor structures include two types of convex units: one is formed by two branches within the same semiconductor structural unit, and the other is formed by two adjacent branches from two adjacent semiconductor structural units in the same column. Furthermore, one type of the convex unit includes drain contact regions, and the other type of the convex unit includes source contact regions and body contact regions.

It should be noted that all the semiconductor structural units in the curved-gate transistor structure are located in the same substrate or the same well region, so the body contact regions of all the semiconductor structural units are at the same potential, since the source contact regions and the body contact regions are connected to the same metal block (each of the first metal blocks M1), the source contact regions of all semiconductor structural units in the curved-gate transistor structure are also at the same potential. When the curved-gate transistor structure is configured as a power transistor, the gate regions of the semiconductor structural units need to be electrically connected to each other (as shown in FIGS. 5a-5b, this connection is realized by the fifth metal block M5) so that they are at the same potential. Similarly, the drain regions of the semiconductor structural units also need to be electrically connected to each other (not shown in figures) to ensure they are at the same potential. When all the semiconductor structural units form a power transistor, the drain contact regions (drain electrodes) of all the semiconductor structural units are at the same potential, and the gate regions of all the semiconductor structural units are also at the same potential.

In some examples, as shown in FIGS. 5a-5b (but without M5), when gate regions are not electrically connected to the same potential, and the semiconductor structural units are in M rows, each of the second metal blocks M2 connects the drain regions of semiconductor structural units in the same column but different rows, while the drain regions of semiconductor structural units in the same row are positioned between the branches of the gate regions, thus, all drain regions in FIGS. 5a-5b are at the same potential. When the 2*M*N (or 2*M when connected gate branches of the same row are considered to be one branch) branches of the gate regions of semiconductor structural units in different rows are connected to 2*M different potentials, the curved-gate transistor structure forms 2*M transistors with common source and drain but different gates. When the branches of the gate regions in the same row of semiconductor structural units are connected to the same potential (i.e., the two branches of the same semiconductor structural unit are at the same potential), and the gate regions of semiconductor structural units in the M rows are connected to M different potentials, the curved-gate transistor structure forms M transistors with common source and drain but different gates. When the 2*M*N branches (each row has N gate regions, each column has M gate regions) of the gate regions are connected to n different potentials (wherein, the N branches on the same row are connected to the same potential, and n is a positive integer, n≤2*M), the curved-gate transistor structure forms n transistors with common source and drain but different gates; based on design requirements, any m*N branches of gate regions can be connected to the same potential to form a transistor (where m is a positive integer, m≤2M), thereby increasing design flexibility.

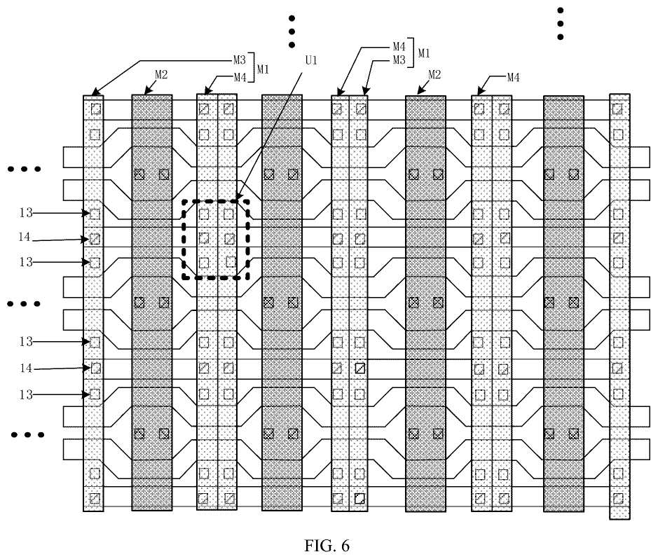

Additionally, it should be noted that the quantity or arrangements of body contact regions 14 in adjacent rows of semiconductor structural units may be different. The quantity and density of body contact regions 14 in adjacent rows can be designed according to the transient overload requirements of the device. When higher transient overload requirements are needed, the quantity or rows of body contact regions 14 can be increased. Conversely, when lower transient overload requirements are needed, the quantity or rows of body contact regions 14 can be decreased. For example, as shown in FIG. 6, compared to FIG. 5a, the body contact regions 14 between each two adjacent rows of semiconductor structural units may be decreased by one row. In other examples, no body contact regions 14 are set between adjacent rows of semiconductor structural units in the intermediate rows. Alternatively, two rows of body contact regions 14 and one row of body contact regions 14 are arranged at intervals, for example, two rows of body contact regions 14 are arranged between a first and second rows semiconductor structural units, one row of body contact regions 14 is arranged between the second and third rows semiconductor structural units, two rows of body contact regions 14 are arranged between the third and fourth rows semiconductor structural units.

In some examples shown in FIG. 2a, FIG. 2b, FIG. 4a, FIG. 4b, FIG. 5a, FIG. 5b, and FIG. 6, there are no contact regions between the first straight segments of the two branches, between the 4k+1th straight segments of the two branches of the gate region of the same semiconductor structural unit, and between the 2k+1th straight segments of adjacent branches of adjacent semiconductor structural units in the same column. In this case, the second metal blocks connected to the drain contact regions and the first metal blocks connected to the source contact regions and body contact regions are arranged parallel and alternately along the first direction.

In some examples, under the condition of meeting the process constraints, first extra contact regions can be provided between the first straight segments of the two branches of the same semiconductor structural unit, and/or between the 4k+1th straight segments of the two branches of the same semiconductor structural unit. The type of these first extra contact regions is consistent with the type of the contact regions in the convex unit. When the convex unit includes both the source contact regions and the body contact regions 14, the first extra contact regions can be either body contact regions or source contact regions. For example, the type of the first extra contact regions can also be the same as the type of contact regions located in the intermediate rows of the convex unit. Second extra contact regions can also be placed between the 2k+1th straight segments of adjacent branches in adjacent semiconductor structural units within the same column, with the type of these second extra contact regions being consistent with the type of contact regions outside the convex unit. When the convex unit outside the semiconductor structural unit includes both source contact regions and body contact regions, the second extra contact regions can be either body contact regions or source contact regions. As an example, the type of the second extra contact regions can be the same as the type of the contact regions in the intermediate rows outside the convex unit. In this case, compared to previous examples where contact regions are only present within the convex unit, the addition of layout contact regions increases the number of contact regions, this increase can enhance the performance of the curved-gate transistor structure. Furthermore, when the said curved-gate transistor structure maintaining the same quantity of contact regions, reducing the device area can increase power density.

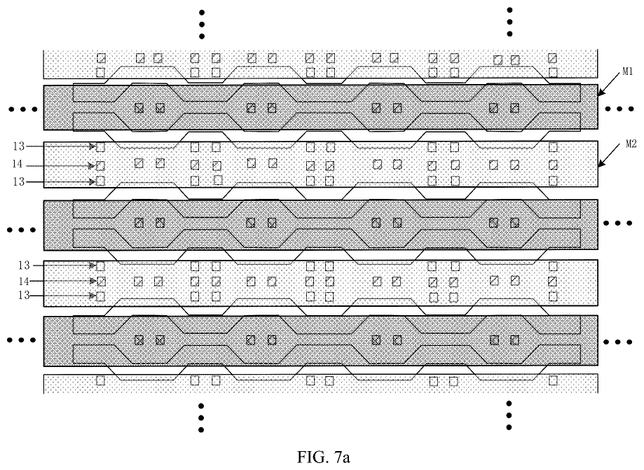

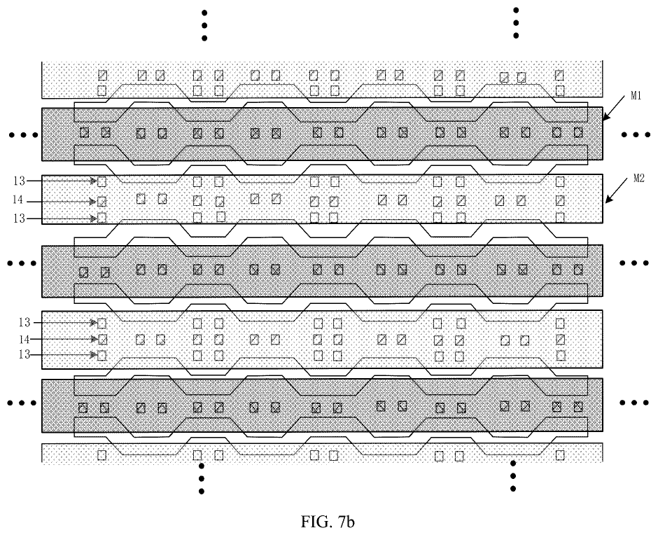

As shown in FIG. 7b, some drain contact regions are set within the convex unit, and some other drain contact regions are also provided between the first straight segments of two branches of the same semiconductor structural unit and between the fifth straight segments of the two branches of the same semiconductor structural unit. Furthermore, the type of the contact regions between the third straight segments of adjacent branches of two adjacent semiconductor structural units in the same column is the same as the type of the contact regions located in the second row outside the convex unit, which may be body contact regions. In this case, only one elongated body doping region is required between adjacent branches of the gate regions of each two adjacent semiconductor structural units in the same column, making the device structure simpler and thereby improving the manufacturing yield of the device.

In other examples, as shown in FIG. 7a, the drain contact regions are present only between the 2k+1th straight segments of adjacent branches of the gate regions of each two adjacent semiconductor structural units in the same column, that is, the drain contact regions are not present between the first straight segments or the 4k+1th straight segments of two branches of the gate regions within the same semiconductor structural unit. Alternatively, the drain contact regions may be only present between the first straight segments and 4k+1th straight segments of branches within the same semiconductor structural unit. As shown in FIG. 5b, one convex unit includes two rows of source contact regions (four in total) and two rows of body contact regions (four in total). As shown in FIG. 7b, the convex unit includes two rows of source contact regions (four in total) and one of body contact regions row (two in total). By providing body contact regions between the third straight segments of adjacent branches of two adjacent semiconductor structural units in the same column, the spacing between the two branches within the same convex unit can be reduced while maintaining the same quantity of contact regions; this configuration helps to decrease the area of the curved-gate transistor structure and increases power density.

As shown in FIGS. 7a-7b, the first metal blocks M1 connected to the drain contact regions, and the second metal blocks M2 connected to the source contact regions and body contact regions, are arranged in parallel and alternately along the second direction. Preferably, similar to the examples shown in FIGS. 5a-5b, when the curved-gate transistor structure is configured as a power transistor, all branches of the gate regions are connected to the same potential. Additionally, the total width of first metal blocks equals the total width of second metal blocks.

As shown in FIGS. 7a-7b, the body contact regions of the semiconductor structural units are at the same potential, since both the source contact regions and body contact regions are connected to the same second metal block M2, the source contact regions of all semiconductor structural units in the curved-gate transistor structure are also at the same potential, when gate regions in different rows are connected to different potentials, or when first metal blocks M1 above drain contact regions in different rows are connected to different potentials, the curved-gate transistor structure can form multiple transistors with common sources. For example, as shown in FIG. 7a, when there are M rows of semiconductor structural units, the branches of the gate regions in the same row are connected to the same potential, and the gate regions of semiconductor structural units in different rows are connected to M different potentials, the curved gate transistor structure forms M transistors with common source connections. In another example, when there are M rows of semiconductor structural units, and the 2*M branches (here, connected gate branches in the same row are considered as one branch) of the gate regions in different rows are connected to 2*M different potentials, respectively, and the curved-gate transistor structure forms 2*M transistors with common sources, where the drain potentials of every pair of transistors are the same. In other examples, adjacent m′ rows of semiconductor structural units can be connected to the same gate potential, and the drain contact regions of adjacent m′ rows can be connected to the same potential, thereby forming a transistor from these adjacent m′ rows (where m′ is a positive integer, m≥M), thereby increasing design flexibility.

Additionally, the contact regions within the same convex unit U1 includes the body contact regions 14 and the source contact regions 13 and exhibit axial and central symmetry in their arrangement, and each row of the contact regions are either all body contact regions or all source contact regions; the contact regions are symmetric about a horizontal axis in the first direction passing through the center of the convex unit U1, and also symmetric about a vertical axis in the second direction passing through the center of the convex unit U1.

For example, as shown in FIGS. 5a-5b, the contact regions within the same convex unit, including the body contact regions and the source contact regions, are arranged in a rectangular array in their arrangement, the quantity of contact regions in each row within the convex unit is the same, and the quantity of contact regions in each column is also the same.

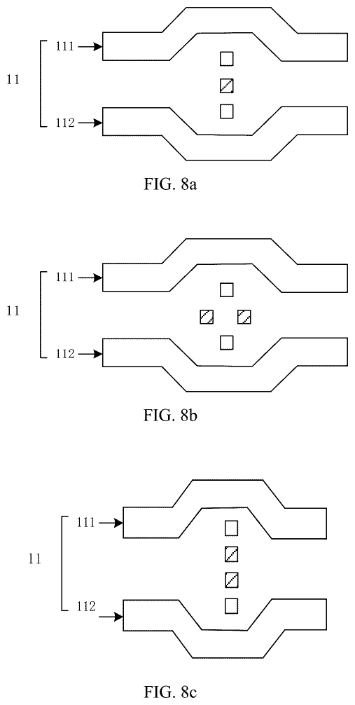

For example, as shown in FIGS. 8a-8b, the contact regions within the same convex unit, including the body contact regions and the source contact regions, are arranged in a single column in their arrangement. In such scenarios where there are stringent size requirements for the device. In this example, arranging the source contact regions and the body contact regions in a single row can enhance the latch-up resistance of the device and relatively save the area of the device.

For example, as shown in FIG. 5a, FIG. 6, FIG. 8a, and FIG. 8b, the source contact regions and the drain contact regions are arranged in an alternating pattern.

To meet device process requirements, there are constraints on the minimum distance between adjacent contact regions and between the contact regions and the gate regions, since the contact regions in the first and last rows of the convex unit are relatively close to the gate region, the quantity of contact regions in each of these rows can be set to be the same, and fewer than the quantity of contact regions in each of the intermediate rows. For example, as shown in FIG. 8b, the quantity of contact regions in each of the first and last rows within the same convex unit is the same, and fewer than the number of contact regions in each of the intermediate rows.

For example, as shown in FIG. 8c, the contact regions in the first and last rows of the same convex unit are of the same type and are different from the contact regions in the intermediate rows. It should be noted that the examples shown in FIGS. 8a-8c are provided solely to explain the quantity and type of contact regions and do not specify whether these are source contact regions or body contact regions. For example, FIG. 8a is intended to demonstrate that source contact regions and body contact regions are arranged in columns and alternately. It does not restrict the layout to having the first and third rows as source contact regions and the second row as body contact regions, nor does it restrict the layout to having the first and third rows as body contact regions and the second row as source contact regions, both types of layouts fall within the scope of the present disclosure.

As described above, the present disclosure provides a curved-gate transistor structure, including M*N semiconductor structural units arranged in an M*N array, wherein M and N are both positive integers; wherein each of the semiconductor structural units includes a gate region, a source region, and a drain region, wherein the source region is located on a first side of the gate region, and the drain region is located on a second side of the gate region, wherein the first side can be an outer side of the gate region, and the second side can be an inner side of the gate region; wherein the gate region of each semiconductor structural unit is curved, wherein each of the semiconductor structural units includes a convex unit surrounded by the gate region of the semiconductor structural unit, and the convex unit has a convex shape; when N>1, gate regions of each two adjacent semiconductor structural units in a same row are connected with each other; and wherein each semiconductor structural unit further includes body contact regions, the body contact regions are connected with a well region or a substrate where the source region and the drain region of the corresponding semiconductor structural unit are located, and wherein the body contact regions and the source region are both on the first side of the gate region; where the present disclosed curved gate regions of the curved-gate transistor structure can increase the channel width and enhance power density of the transistor structure; the diagonal design of the source contact regions and the drain contact regions impart certain ESD protection characteristics to each of the semiconductor structural units, enhancing the current-limiting capability of the source and drain; in each gate region, the angles between the adjacent straight segments are obtuse, which reduces the likelihood of local avalanche breakdown compared to designs with 90° or acute angles, thereby enhancing stability of the transistor structure; the body contact regions are added near the source region, and the contact regions can easily form a network to enhance latch-up resistance, by adjusting the density of the body contact regions and the relative arrangement between the body contact regions and the drain contact regions according to design requirements, the transistor structure can better handle frequent transient overload situations without excessively increasing the area; when all semiconductor structural units form a power transistor, the total width of all the first metal blocks is equal to that of all the second metal blocks, this design not only increases current capability but also improves the uniformity of the current; in each of the semiconductor structural units, contact holes may be set between the first straight segments of the two branches and between the 4k+1th straight segments of the two branches, and contact holes may also be set between the 2k +1th straight segments of adjacent branches in neighboring semiconductor structural units aligned in the same column; this arrangement increases the number and placement of contact holes, thereby enhancing the performance and power density of the device; according to design requirements, the two branches of the gate regions of the same semiconductor structural unit can be connected to same or different potentials, wherein each of gate branches and each of the first metal blocks can also be connected to a same or different potential; this flexibility allows for the configuration of one or more common-source transistors from all semiconductor structural units, enhancing design adaptability.

Although the embodiments or implementations are described separately, common technical aspects may be interchangeable and integratable between them. For content not explicitly stated in one embodiment or implementation, refer to the details provided in another embodiment.

According to the embodiments of the present disclosure as described above, these examples do not detail all specifics and do not limit the invention to only the described implementations. Clearly, many modifications and variations can be made based on the above description. These embodiments are selected and specifically described in this specification for the purpose of better explaining the principles and practical applications of the present disclosure, so that those skilled in the art to which it belongs can make good use of the present disclosure as well as the modified use on the basis of the present disclosure. The present disclosure is limited only by the claims and their full scope and equivalents.

What is claimed is:

1. A curved-gate transistor structure, comprising M*N semiconductor structural units arranged in an M*N array, wherein M and N are both positive integers; wherein each of the semiconductor structural units comprises a gate region, a source region, and a drain region, wherein the source region is located on a first side of the gate region, and the drain region is located on a second side of the gate region;
wherein the gate region of each semiconductor structural unit is curved, wherein each of the semiconductor structural units comprises a convex unit surrounded by the gate region of the semiconductor structural unit, and the convex unit has a convex shape; and
wherein each semiconductor structural unit further comprises body contact regions, the body contact regions are connected with a well region or a substrate where the source region and the drain region of the corresponding semiconductor structural unit are located, and wherein the body contact regions and the source region are both on the first side of the gate region.

2. The curved-gate transistor structure according to claim 1, wherein the gate region of each semiconductor structural unit comprises two curved branches, and the two branches are separated from each other and located above an active region where the semiconductor structural unit is located;
wherein each of the branches of the gate region is symmetric with respect to a first straight line, and the two branches are symmetric with respect to a second straight line; wherein the first straight line and the second straight line both pass through a center of the semiconductor structural unit and are perpendicular to each other; and
wherein when N>1, branches of the gate regions of each two adjacent semiconductor structural units in the same row are correspondingly connected with each other.

3. The curved-gate transistor structure according to claim 1, wherein in each semiconductor structural unit, either the source region or the drain region is located within the convex unit.

4. The curved-gate transistor structure according to claim 2, wherein each of the branches of the gate region of each semiconductor structural unit comprises multiple straight segments, and wherein angles between adjacent straight segments are obtuse angles.

5. The curved-gate transistor structure according to claim 4, wherein junctions between the adjacent straight segments of each of the branches are arced.

6. The curved-gate transistor structure according to claim 1, wherein each semiconductor structural unit further comprises one or more drain contact regions and one or more source contact regions; wherein the drain contact regions are located on the drain region, and wherein the source contact regions are located on the source region.

7. The curved-gate transistor structure according to claim 2, wherein each branch of the gate region of each semiconductor structural unit comprises 4k+1 straight segments, wherein a first straight segment, a 2k+1th straight segment and a 4k+1th straight segment of each branch are parallel to each other, and wherein k is a positive integer.

8. The curved-gate transistor structure according to claim 7, wherein in each semiconductor structural unit, contact regions are provided between first straight segments of the two branches of the gate region, and between 4k+1th straight segments of the two branches of the gate region.

9. The curved-gate transistor structure according to claim 7, wherein when M>1, contact regions are provided between 2k+1th straight segments of two adjacent branches of two adjacent semiconductor structural units located in the same column.

10. The curved-gate transistor structure according to claim 2, wherein each semiconductor structural unit further comprises first metal blocks and second metal blocks, wherein the second metal blocks are connected to the drain contact regions, and wherein the first metal blocks are connected to the source contact regions and the body contact regions;
wherein the first metal blocks and the second metal blocks are parallel and alternating in a width direction of the semiconductor structural unit.

11. The curved-gate transistor structure according to claim 10, wherein the first metal blocks and the second metal blocks are parallel and alternating along a first direction, wherein the first metal blocks and the second metal blocks have equal lengths along a second direction, wherein the first direction is parallel to the first straight segment of each branch of the gate region in each semiconductor structural unit, and wherein the second direction is perpendicular to the first direction.

12. The curved-gate transistor structure according to claim 10, wherein the first metal blocks and the second metal blocks are parallel and alternating along a second direction, wherein the first metal blocks and the second metal blocks have equal lengths along a first direction, wherein the first direction is parallel to the first straight segments of each branch of the gate region in each semiconductor structural unit, and wherein the second direction is perpendicular to the first direction.

13. The curved-gate transistor structure according to claim 10, wherein when M>1, all branches of the gate regions of the curved-gate transistor structure are connected to a same potential through a fifth metal block.

14. The curved-gate transistor structure according to claim 10, wherein when M>1, gate regions of the semiconductor structural units located in different rows are connected to different potentials.

15. The curved-gate transistor structure according to claim 10, wherein the two branches of each semiconductor structural unit are connected to two different potentials.

16. The curved-gate transistor structure according to claim 12, wherein each of the first metal blocks is connected to a different potential.

17. The curved-gate transistor structure according to claim 12, wherein some of the first metal blocks are connected to a same potential.

18. The curved-gate transistor structure according to claim 1, wherein contact regions within each convex unit comprises the body contact regions and the source contact regions and exhibit axial and central symmetry in their arrangement, and wherein each row of the contact regions are either all body contact regions or all source contact regions.

19. The curved-gate transistor structure according to claim 18, wherein the source contact regions and the body contact regions are alternately arranged in one column.

20. The curved-gate transistor structure according to claim 18, wherein a quantity of contact regions in a first row within each convex unit is the same as that of a last row, and less than that of each intermediate row.
